(19) United States
(12) Patent Application Publication
(10) Pub. No.: US 2003/0026576 A1
(43) Pub. Date: Feb. 6, 2003

(54) Reducing optical loss in semiconductor opto-electronic devices by hydrogen passivation of dopants

(76) Inventors: Waleed A. Asous, Allentown, PA (US); Aaron Eugene Bond, Allentown, PA (US); Robert Louis Hartman, Warren Township, NJ (US); Padman Parayanthal, Clinton Township, NJ (US); George John Przybylek, Douglasville, PA (US); Gleb E. Shtengel, New Providence, NJ (US)

Correspondence Address: CHRISTIE, PARKER & HALE, LLP, 350 WEST COLORADO BOULEVARD, SUITE 500, PASADENA, CA, 91105, US

(21) Appl. No.: 09/922,891

(22) Filed: Aug. 6, 2001

(51) Int. Cl. G02B 6/10; H01L 21/04

(52) U.S. Cl. 385/131; 385/142; 438/510

(57) ABSTRACT

A method for reducing optical loss in opto-electronic devices includes passivating P-type dopant impurities formed within various cladding and contact layer films. The passivating species is atomic hydrogen produced by a hydrogen containing plasma. The atomic hydrogen complexes with P-type dopant impurities to form electrically neutral pairs which are void of free carriers. Absorption, and loss, of the optical wave is therefore suppressed as it propagates through the P-doped layers because of the reduced free carrier concentration in the P-doped layers.

### FIELD OF THE INVENTION

The present invention relates, most generally, to semiconductor opto-electronic devices and methods for forming the same. More particularly, the present invention provides a method for passivating P-type dopants, thereby reducing free carrier concentration and improving the optical power of the devices. The present invention also relates to semiconductor opto-electronic devices formed by such methods.

### BACKGROUND OF THE INVENTION

It is desirable to minimize optical loss and to maximize optical power within opto-electronic devices such as lasers and other waveguide devices. Toward this end, anti-reflective coatings (ARC) have been used at the end of the opto-electronic device through which the propagated optical beam exits. The use of an ARC minimizes internal reflection of the propagating optical beam as it exits the opto-electronic device. Low reflectivity of the output facet is also necessary to improve wavelength chirp and noise characteristics of the electro-absorption modulated lasers.

Another manner by which internal reflection is minimized is the incorporation of a window region within an opto-electronic device. The window region is void of the multiple quantum well waveguide layer and forms the last section through which the propagated optical beam passes as it exists the opto-electronic device. In the window region, the beam diffracts and becomes loosely confined and the reflection of the beam back into the waveguide is minimized. In this window region, the beam is propagated through highly doped P-type layers such as P-type cladding layers and P-type contact layers, as the multiple quantum well layer is absent in the window region. A high dopant concentration is necessary in these layers to ensure low series resistance and good electrical contact. The light beam-confining ability of the waveguide device depends upon the differences of the refractive indices between the cladding layers which surround the waveguide layer, and the waveguide layer. Typically, a high concentration of P-type dopant atoms on the order of 10¹⁸ atoms/cm³ is used in the P-type cladding layers. Each P-type dopant includes at least one hole, or free carrier, associated with it. A P-type dopant may include multiple holes or free carriers depending on the valence level of the P-type dopant species used.

In the window section where the optical beam is loosely confined due to the absence of the multiple quantum well layer, optical power is lost due to the absorption of the optical beam by the holes or free carriers. The window section is where the loosely confined optical beam “spreads out” and passes through a larger volume of P-doped layers which include a high concentration of P-type dopants as discussed above.

It is an object of the present invention to reduce optical loss due to free carrier absorption, particularly in the window region. Another object of the present invention is to reduce optical loss as above, while maintaining a suitably high P-type dopant concentration within the cladding layers to ensure good beam-confining abilities of the opto-electronic device and suitably low contact resistance.

### SUMMARY OF THE INVENTION

The present invention provides an opto-electronic device exhibiting reduced optical loss and maximum optical power by providing an opto-electronic device having a window structure void of a multiple quantum well layer so as to reduce reflection and allow for a loosely confined optical beam to be propagated through this window section, as it exits the device. The free carrier concentration in the P-doped layers in the window section is reduced in comparison to the free carrier concentration in the same P-doped layers in other sections of the opto-electronic device such as the light propagation section. Additionally, the total number of free carriers per unit length of the P-doped layers is reduced in the window section because of a reduced P-doped layer thickness in the window area. As a result, optical loss due to free carrier absorption is minimized.

The method for forming this structure includes using a reactive ion etch process including a hydrogen-containing plasma to etch away part of the P-doped layers which include a P-contact layer and a P-cladding layer, from the window section. The reactive ion etch process also passivates the portions of the P-doped layers which remain in the window section. Atomic hydrogen from the hydrogen-containing plasma passivates the P-type dopant impurities within the P-doped layers by coupling with the P-type dopant to form an electrically neutral pair. In this manner, the free carrier or hole concentration in the window section of the P-type layer is reduced with respect to the free carrier concentration in the P-type layers in other sections while the atomic dopant concentration of the P-type dopant atoms is the same throughout the various sections of the P-type layer. Furthermore, free carrier concentration is reduced for a given concentration of P-type dopant atoms.

### BRIEF DESCRIPTION OF THE DRAWING

The invention is best understood from the following detailed description when read in conjunction with the accompanying drawing. It is emphasized that, according to common practice, the various features of the drawing are not to-scale. On the contrary, the dimensions of the various features are arbitrarily expanded or reduced for clarity. Included in the drawing are the following figures:

FIG. 1 is a cross-sectional view of an opto-electronic device including a window section;

FIG. 2 shows the opto-electronic device of FIG. 1 being etched according to the method of the present invention; and

FIG. 3 is a cross-sectional view showing the etched and passivated opto-electronic device according to an exemplary embodiment of the present invention.

Like numerals refer to like features throughout the figures and specification.

### DETAILED DESCRIPTION OF THE INVENTION

The present invention relates to opto-electronic devices such as lasers and other waveguide devices. The present invention provides a method for the atomic hydrogen passivation of P-type dopant impurities to reduce the free carrier concentration associated with a fixed atomic P-type dopant concentration. The present invention also provides the opto-electronic device formed by this method and which exhibits increased optical power and reduced optical loss as a result of a reduced number of free carriers in the window section as compared to the free carrier concentration in the same p-doped layers having the same atomic p-dopant impurity concentrations within other sections of the opto-electronic device.

FIG. 1 is a cross-sectional view showing an exemplary opto-electronic device including a window section. Opto-electronic device 99 is a waveguide structure including light propagation section 23, modulator section 25, and window section 27. According to an exemplary embodiment in which opto-electronic device 99 is a laser, light propagation section 23 may be referred to as the lasing, or laser secton. According to other exemplary embodiments, the device may not include the modulator section. For matters of completeness, the device will be described hereinafter, to include the modulator secton.

The semiconductor device is formed on semiconductor substrate 1 using conventional methods. Semiconductor substrate 1 may be an InP wafer, a silicon wafer or other semiconductor substrates commonly used in the semiconductor opto-electronics industry. Semiconductor substrate 1 may be N-type doped substrate or it may include an N-type cladding layer forming the upper surface of the structure shown as semiconductor substrate 1. In an exemplary embodiment, this N-type cladding layer may comprise n-InP.

Opto-electronic device 99 formed above the substrate 1 includes lower N-type cladding layer 3, multiple quantum well, or waveguide layer 5, upper P-type cladding layer 9, and P-type contact layer 11.

According to an exemplary embodiment, lower N-type cladding layer 3 may be n-InP, but other suitable N-type cladding layers may be used alternatively. It can be seen that lower N-type cladding layer 3 extends through light propagation section 23, modulator section 25, and window section 27. Multiple quantum well (MQW) layer 5 is an intrinsic film through which an optical beam is propagated, and extends through each of light propagation section 23 and modulator section 25. Lower N-type cladding layer 3 and MQW layer 5 may be considered the device substructure. According to another exemplary embodiment, an additional un-doped layer may be interposed between MQW layer 5 and lower N-type cladding layer 3.

It can be seen that section 15 of MQW layer 5 within modulator section 25, includes reduced thickness 17 which is less than bulk thickness 7 of MQW layer 5 in light propagation section 23. MQW layer 25 provides a higher band gap in modulator section 25 in order to modulate the optical beam which is propagated from left to right according to the exemplary structure shown in FIG. 1. Light propagation section 23 includes length 33 which may range from 500 microns to 1000 microns according to various exemplary embodiments. Modulator section 25 includes length 35 which may range from 100 microns to 250 microns according to various exemplary embodiments. Window section 27 includes length 37 which may range from 5 microns to 50 microns according to various exemplary embodiments. As noted above, various features of the opto-electronic device shown in FIG. 1 have been expanded for clarity and the opto-electronic device is not therefore drawn to scale. According to the exemplary embodiment shown to include light propagation section 23, modulator section 25 and window section 27, the opto-electronic device may serve as an EML (electro absorption modulated laser) device, but other opto-electronic devices may be used alternatively.

Intrinsic, or un-doped MQW layer 5 may be formed of conventional waveguide layer material such as InGaAs and InGaAsP, but other suitable waveguide materials may be used to form MQW layer 5. For each of exemplary waveguide layers InGaAs and InGaAsP, any suitable combination of the elements used to form the respective layers, may be used. MQW layer 5 includes bulk thickness 7 which may range from 200 to 400 nanometers within light propagation section 23 and also includes reduced thickness 17 in modulator section 25. According to an exemplary embodiment, reduced thickness 17 may be 40 percent smaller than bulk thickness 7 of MQW layer 5. According to alternative embodiments, other relative thickness reductions for reduced thickness 17 in comparison to bulk thickness 7, may be used.

Upper P-type cladding layer 9 is formed over MQW layer 5 in each of light propagation section 23 and modulator section 25, and directly over lower N-type cladding layer 3 within window section 27. Upper P-type cladding layer 9 will include bulk thickness 29 which may range from 1500 nm to 4500 nm according to various exemplary embodiments but other thicknesses may be used alternatively. The material used to form upper P-type cladding layer 9 may be P-doped InP, but other suitable P-doped cladding layers may be used alternatively. According to an exemplary embodiment, the P-type impurity species used as a dopant in P-type cladding layer 9, may be zinc. According to alternative embodiments, other P-type dopant impurities may be used. A typical dopant concentration of P-type dopant impurities within upper P-type cladding layer 9 may be 2×10¹⁸ atoms/cm³, but other dopant impurity concentrations in the 10¹⁸ atoms/cm³ range, may be used. According to various exemplary embodiments, the P-type atomic dopant concentration within upper P-type cladding layer 9 may range from 2×10¹⁷ atoms/cm³ to 5×10¹⁸ atoms/cm³. This high dopant concentration within upper P-type cladding layer 9 is necessary to provide low sheet resistance and minimize contact resistance in the light propagation 23 and modulator 25 sections of the device. Upper P-type cladding layer 9 includes portion 21 in window section 27. Portion 21 of upper P-type cladding layer 9 within window section 27 may include a thickness which is greater than bulk thickness 29 of upper P-type cladding layer 9 within regions 23 and 25.

Contact layer 11 is formed over upper P-type cladding layer 9 in each of light propagation section 23, modulator section 25, and window section 27. Contact layer 11 is a P-doped layer which may be formed of InGaAs according to an exemplary embodiment, but other P-doped contact layers may be used alternatively. Contact layer 11 includes upper surface 13 and thickness 31. Thickness 31 may be a thickness within the range of 50 nm to 200 nm according to various exemplary embodiments but other thicknesses may be used alternatively. According to an exemplary embodiment, thickness 39 which represents the sum of the thickness of P-type contact layer 11 and upper P-type cladding layer 9 within window section 27 may range from 1550 to 4700 nm according to various exemplary embodiments. As an optical beam travels left to right according to the exemplary embodiment shown in FIG. 1, the optical beam becomes loosely confined within window section 27 then exits the opto-electronic device structure through mirror end 19 of the opto-electronic device.

Each of lower N-type cladding layer 3, MQW layer 5, upper P-type cladding layer 9, and P-type contact layer 11 may be formed using conventional methods. According to an exemplary embodiment, metallo-organic chemical vapor deposition (MOCVD) may be used, but other film formation processes may be used alternatively. P-doped layers 9 and 11 may have P-type dopant impurities introduced into the respective films, in-situ, during the film formation process, or dopants may be introduced after each respective film formation is complete. It should be noted at this point that the free carrier, or hole concentration of the p-doped layers represents the atomic concentration of the P-type dopant impurities within the film, multiplied by the number of holes per dopant atom of the P-type dopant impurity used.

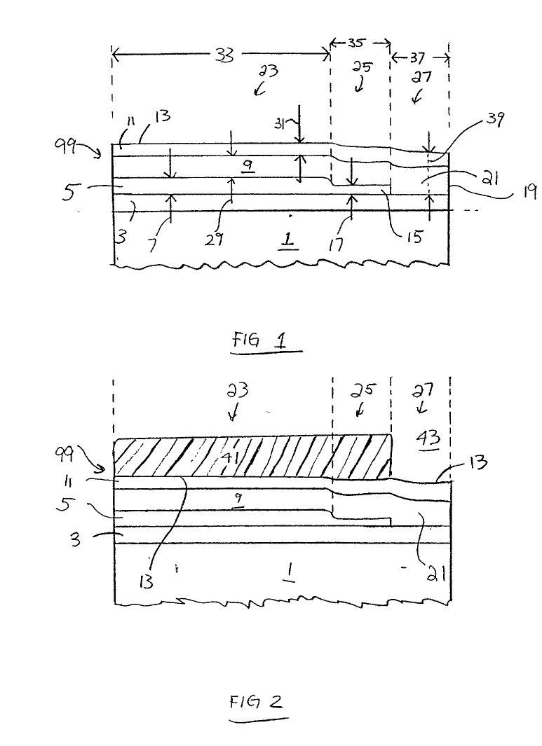

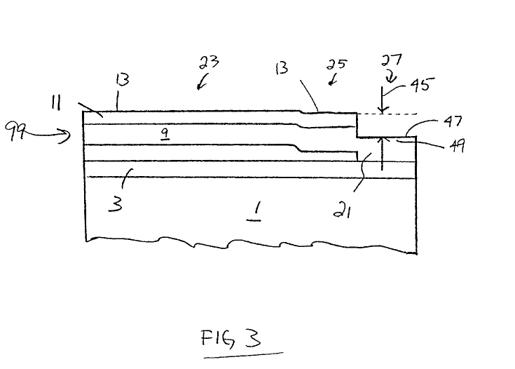

The exemplary embodiment shown in FIG. 1 includes mirror end 19. According to an exemplary embodiment, mirror end 19 may be formed by etching to remove portions of layers 3, 9 and 11 from over substrate 1. According to another exemplary embodiment, the opto-electronic device shown in FIG. 1 may be formed as a section of a continuous structure including multiple opto-electronic devices arranged end-to-end. According to this exemplary embodiment, mirror end 19 is produced by cleaving process used to cleave the substrate and separate the individual opto-electronic devices, after the process operations discussed in conjunction with FIGS. 2 and 3 are carried out.

Now turning to FIG. 2, a pattern is formed of masking film 41 over opto-electronic device 99 shown in FIG. 1. It can be seen that masking film 41 covers opto-electronic device 99 in light propagation section 23 and modulator section 25 but leaves upper surface 13 of P-type contact layer 11 exposed within window region 27. Masking film 41 may be a photosensitive film such as photoresist as shown in FIG. 2. The pattern within masking film 41 may be formed using conventional means. According to alternative embodiments, other masking films such as oxide materials (not shown) may be used alternatively. In either case, the masking material covers opto-electronic device 99 in light propagation section 23 and modulator section 25 while exposing upper surface 13 in window section 27. It is understood that the masking process may be performed on a wafer containing many devices formed end-to-end before a cleaving process is used to separate the individual opto-electronic devices such as opto-electronic device 99 shown on FIG. 2. According to this exemplary embodiment in which individual opto-electronic devices 99 are formed by cleaving, mirror ends 19 are produced by the cleaving process and are not present during the patterning process shown in FIG. 2, nor the etching process shown in FIG. 3.

After masking film 41 is formed and patterned as shown in FIG. 2, opto-electronic device 99 is exposed to a hydrogen-containing plasma 43 and a reactive ion etching process is carried out. The reactive ion etching (RIE) process is used to etch away portions of P-type contact layer 11 and possibly upper P-type cladding layer 9 which are exposed within window section 27. Portions of P-type layers 11 and 9 which remain within window section 27 are passivated by atomic hydrogen from hydrogen-containing plasma 43.

According to an exemplary embodiment, the etching process produces hydrogen-containing plasma 43 by using an etchant gas mixture of CH₄ and H₂. Additional components such as argon or nitrogen may be added to the etchant gas mixture. According to an exemplary embodiment, CH₄ and H₂ form the etchant gas mixture with CH₄ having a weight percentage within the etchant gas mixture ranging from 4 to 20%. Other mixtures may be used alternatively. The gas flow rate of the etchant gas mixture may range from 50 to 100 sccm (standard cubic centimeters per minute) when carried out in a Plasma-Therm™ 400 series reactor using a 14 inch Al₂O₃ coated aluminum susceptor plate. The use of the Plasma-Therm etcher is intended to be exemplary only, and the present invention may be carried out using any of various RIE etching tools currently available in the art. Gas flow rates may vary accordingly for other reactors and may also include values outside of the 50-100 sccm range when the Plasma-ThermTm™ 400 system is used. During the reactive ion etching process, various etching powers may be used, and in an exemplary embodiment, the etching power may range from 50-200 watts. In an exemplary embodiment, the etching pressure may fall within the range of 20-100 millitorr (mT) but other pressures and powers may be used alternatively.

FIG. 3 shows the structure of FIG. 2 after it has been etched using the above-described etching process and also after masking film 41 has been subsequently removed. Conventional methods may be used to remove masking film 41 from opto-electronic device 99. Within window section 27, it can be seen that a portion of the composite film including upper P-type cladding layer 9 and P-type contact layer 11, has been removed by the above-described etching process. Etch depth 45 represents the amount of the composite film removed by etching. According to various exemplary embodiments, etch depth 45 may range from 500 to 1000 nanometers but other etch depths may be used alternatively. According to another exemplary embodiment, etch depth 45 may be chosen to remove P-type contact layer 11 and to recess upper P-type cladding layer 9 by a depth of 500 to 1000 nanometers. According to the exemplary embodiment shown in FIG. 3, the entire thickness of P-type contact layer 11 has been removed from window section 27. Receded surface 47 now forms the top surface of portion 21 of upper P-type cladding layer 9 which remains in window section 27. Although FIG. 3 shows that the entire P-type contact layer 11 has been removed from window section 27 according to the etching process of the present invention, according to various alternatives and embodiments, etch depth 45 may be chosen to be less than thickness 31 of P-type contact layer 11 (as shown in FIG. 1) so that the entire thickness of P-type contact layer 11 is not removed from window section 27.

During the reactive ion etching process described in conjunction with FIG. 2, energized atomic hydrogen from the hydrogen-containing plasma diffuses into the exposed surface of the P-doped layer in window section 27. As shown in FIG. 3, portions of P-type contact layer 11 have been removed from window section 27 by etching, to expose receded surface 47 of portion 21 of upper P-type cladding layer 9. Portion 21 of upper P-type cladding layer 9 is passivated by the atomic hydrogen ions from hydrogen containing plasma 43 which diffuse through receded surface 47 and into portion 21 of upper P-type cladding layer 9. Similarly, if etch depth 45 is chosen to remove less than the total thickness 31 of P-type contact layer 11 from window section 27, the portions of P-type contact layer 11 which remained in window section 27, would also be passivated. Depending on etch depth 45 and the etching power and pressure and the other etching conditions used, atomic hydrogen may additionally diffuse through portion 21 and into portions of lower N-type cladding layer 3 which are formed within window section 27.

Regardless of the depth of hydrogen atom diffusion into the P-type layer or layers within window section 27, the hydrogen atoms enter the p-doped materials within window section 27 and passivate free carriers, or holes associated with the P-type dopants included within this region. A hydrogen atom or hydrogen atoms complex with P-type dopants to form an electrically-neutral pair. For example, a hydrogen atom may combine or complex with zinc to form a Zn—H pair. Stated alternatively, the hydrogen atoms passivate the P-type dopant species and thereby reduce the free carrier concentration. In this manner, even though the atomic dopant concentration of the P-type dopant impurities remain the same, the number of holes or free carriers associated with the P-type dopant impurities within this region, is reduced. Even though upper P-type cladding layer 9, for example will have a substantially uniform atomic dopant concentration of P-type dopant impurities throughout the film, the concentration of free carriers associated with the P-type dopant impurities within window section 27 is reduced relative to that in other sections of upper P-type cladding layer 9. Furthermore, it can be understood that there are less free carriers per unit length of the opto-electronic device 99 within a composite layer consisting of upper P-type cladding layer 9 and P-type contact layer 11 within window region 27, because the composite film thickness of upper P-type cladding layer 9 and P-type contact layer 11 (shown as thickness 39 in FIG. 1) is reduced within window region 27 when compared to the thickness of the composite film in the other unetched areas.

Hydrogen atoms from the energized, hydrogen-containing plasma complex with the P-type dopant impurity atom by filling the hole contained by the P-type dopant impurity. Stated alternatively, a hole or free carrier associated with the P-type dopant impurity, is eliminated.

According to an exemplary embodiment, the hole concentration within upper P-type cladding layer 9 as formed, and as remains within light propagation section 23 and modulator section 25, may be a concentration within the range of 3×10¹⁷ holes/cm³ to 3×10¹⁸ holes/cm³. After the passivating process according to the present invention, the hole concentration within passivated portion 21 of upper P-type cladding layer 9 within window section 27 may be a concentration within the range of 1×10¹⁶ holes/cm³ to3×10¹⁶ holes/cm³. Yet, the atomic dopant impurity concentrations within the respective sections, remains the same. It should be understood that, according to various alternative embodiments, the original atomic and hole concentrations may be varied. It should be further understood that, depending on the process conditions used during the reactive ion etch process, the hole concentration in portion 21 of upper P-type cladding layer 9 may be reduced by various degrees. In either case, for a given atomic concentration of dopant impurities which remains fixed through the passivation process, the free carrier or hole concentration associated with the atomic P-dopant concentration is reduced within the window section 27, while it remains unchanged in light propagation section 23 and modulator section 25.

It should be understood that the hydrogen passivation procedure described above may be used in conjunction with various semiconductor opto-electronic devices such as other waveguides and lasers, modulators, and EML's. In each application, a pre-determined section of the originally p-doped layer or layers may be passivated and the hole or free carrier concentration within that area will be reduced, even though the atomic dopant concentration remains fixed within that area.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principals of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents such as equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed:

1. A method for forming a semiconductor opto-electric device comprising the steps of:
forming a waveguide device including a propagation section and a window section, said waveguide device including an upper P-type layer within said propagation section and said window section and having a first thickness within said window section; and
exposing said window section to a hydrogen-containing plasma to etch said upper P-type layer within said window section, thereby reducing said first thickness, and to passivate portions of said upper P-type layer which remain in said window section, with hydrogen from said hydrogen-containing plasma.

2. The method as in claim 1 wherein said step of exposing includes said hydrogen complexing with Zn within said upper P-type layer.

3. The method as in claim 1, wherein said upper P-type layer comprises a composite film including a P-type contact layer superjacent a P-type upper cladding layer.

4. The method as in claim 3, wherein said P-type contact layer comprises P-type InGaAsP, and said P-type upper cladding layer comprises P-type InP.

5. The method as in claim 1, wherein the waveguide device comprises a laser having a length and opposed ends and the window section forms at least one of the opposed ends.

6. The method as in claim 3, in which said step of forming includes forming each of said P-type contact layer and said P-type upper cladding layer using metallo-organic vapor phase epitaxy (MOVPE).

7. The method as in claim 1, wherein said upper P-type layer comprises a P-type contact layer superjacent a P-type upper cladding layer, and in which said step of forming includes
said waveguide device further including a modulator section, and providing a device substructure including a lower N-type cladding layer formed within each of said propagation section, said modulator section and said window section, and a multiple quantum well layer formed in each of said propagation section and said modulator section, and
sequentially forming each of said P-type upper cladding layer and said P-type contact layer over said device substructure.

8. The method as in claim 1, wherein said step of exposing comprises reactive ion etching using an etchant gas mixture including CH₄ and H₂ as etchant gases.

9. The method as in claim 8, in which said step of exposing includes said CH₄ etchant gas having a weight percentage ranging from 4% to 20% of said etchant gas mixture.

10. The method as in claim 8, in which said step of exposing comprises reactive ion etching and includes said etchant gas mixture having a flow rate within the range of 50 sccm to 100 sccm, a plasma pressure within the range of 20 millitorr to 100 millitorr, and an etch power within the range of 50 watts to 200 watts.

11. The method as in claim 1, in which step of forming includes providing said upper P-type layer having said first thickness within the range of 1550 to 4700 nanometers, and in which said step of exposing includes reducing said first thickness by an amount within the range of 500 to 1000 nanometers.

12. The method as in claim 1, in which step of exposing includes patterning by forming a masking layer over said propagation section and thereby exposing said window section, and
further comprising the step of removing said masking layer.

13. A waveguide device comprising a propagation section and a window section and formed of:
a lower N-type cladding layer formed in each of said propagation section and said window section;
an intrinsic multiple quantum well layer formed over said lower N-type cladding layer in said propagation section;
an upper P-type cladding layer formed over said multiple quantum well layer in said propagation section and over said lower N-type cladding layer in said window section; and
a contact layer formed over said upper P-type cladding layer in said propagation section,
said upper P-type cladding layer having a first hole concentration in said propagation section and a second hole concentration being less than said first hole concentration in said window section.

14. The waveguide device as in claim 13, wherein said upper P-type cladding layer has a first thickness in said propagation section and a second thickness being less than said first thickness in said window section.

15. The waveguide device as in claim 13, wherein said upper P-type cladding layer includes P-type atomic dopants therewithin and further includes a first atomic concentration of said P-type atomic dopants in said propagation section, and a second atomic concentration of said P-type atomic dopants in said window section, said first atomic concentration and said second atomic concentration being essentially equal.

16. The waveguide device as in claim 13, wherein said waveguide device comprises a laser which extends longitudinally and each of said propagation section and said window section form a longitudinal segment thereof, and further comprising a modulator section interposed between said propagation section and said window section,
said modulator section including said contact layer formed over said upper P-type cladding layer formed over said intrinsic multiple quantum well layer formed over said lower N-type cladding layer, said intrinsic multiple quantum well layer having a first thickness in said modulator section and a second thickness being greater than said first thickness, in said propagation section.

17. The waveguide device as in claim 13, in which said upper P-type cladding layer includes Zn as a P-type dopant therein.

18. The waveguide device as in claim 13, in which said first hole concentration comprises a concentration within the range of 3×10¹⁷ holes/cm³ to 3×10¹⁸ holes/cm³, and wherein said second hole concentration comprises a hole concentration ranging from 1×10¹⁶ holes/cm³ to 3×10¹⁶ holes/cm³.

19. The waveguide device as in claim 13, in which said multiple quantum well layer comprises intrinsic InGaAsP, each of said lower N-type cladding layer and said upper P-type cladding layer comprise InP, and said contact layer comprises InGaAs.

20. The waveguide device as in claim 13, wherein, in said propagation section, said contact layer includes a thickness within the range of 50 nm-200 nm and said upper P-type cladding layer comprises a first thickness ranging from 1500 nm to 4500 nm, and in said window section, said upper P-type cladding layer includes said thickness being less than said first thickness by 500-100 nm.
